(19) United States
(12) Patent Application Publication
(10) Pub. No.: US 2010/0284162 A1
(43) Pub. Date: Nov. 11, 2010

(54) ELECTRONIC DEVICE

(75) Inventor: Zhan-Yang Li, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/537,665

(22) Filed: Aug. 7, 2009

(30) Foreign Application Priority Data
May 11, 2009 (CN) 200920303037.6

(51) Int. Cl. H05K 9/00

(52) U.S. Cl. 361/818

(57) ABSTRACT

An electronic device is provided. The electronic device includes a base, a power supply chassis mounted in the base, and a shielding member. The power supply chassis defines a receiving space. A power supply is accommodated in the power supply chassis and occupies part of the receiving space. The power supply and the power supply chassis cooperatively define an opening. The shielding member blocks the opening. A securing slot is defined in the power supply chassis. An elastic securing member is formed on the shielding member and engages with the securing slot.

### BACKGROUND

1. Technical Field

The present disclosure relates to electronic devices, and particularly, to an electronic device with an electromagnetic interference (EMI) shielding member.

2. Description of Related Art

Power supply is an important component used in electronic devices, such as computers or servers. For example, in a server system, many power supplies may be used to provide power to many different components in the server system. The power supplies are mounted in a power supply chassis that is secured to an enclosure. However, in some circumstances, the server system doesn't need so many power supplies. One or more power supplies may be removed from the power supply chassis leaving empty space. A fully loaded power supply chassis provides an additional benefit of helping to block electromagnetic interference (EMI), but this benefit may be lost if there is empty space in the chassis.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device with an EMI shielding member.

FIG. 2 is similar to FIG. 1, but viewed from another aspect.

FIG. 3 is an enlarged view of the EMI shielding member.

FIG. 4 is an assembled view of FIG. 1.

FIG. 5 is similar to FIG. 4, but viewed from another aspect.

### DETAILED DESCRIPTION

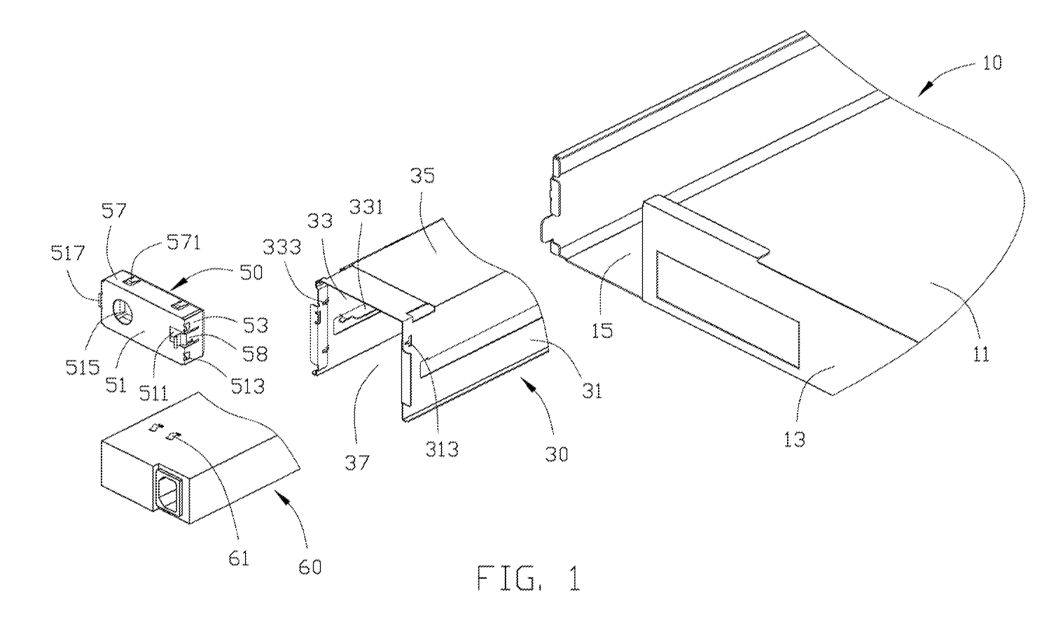

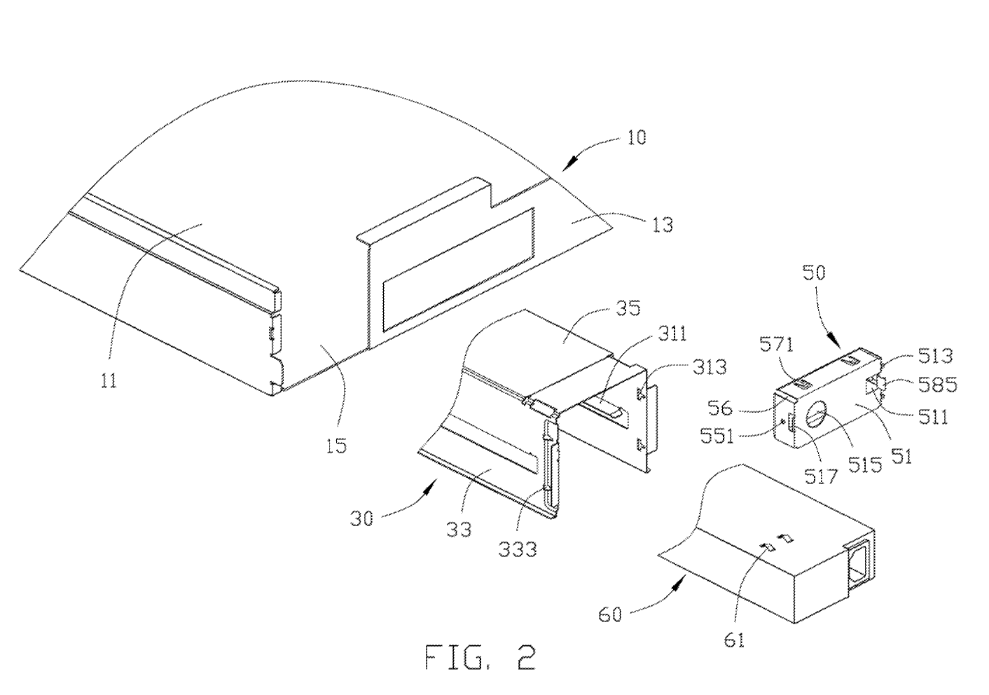

Referring to FIGS. 1 and 2, an embodiment of an electronic device, such as a computer, includes a base 10, a power supply chassis 30, a power supply 60 accommodated in a receiving space defined by the power supply chassis 30, and an electromagnetic interference (EMI) shielding member 50. The power supply 60 includes two elastic clips 61 formed on a top thereof.

The base 10 includes a bottom wall 11 and a rear wall 13 perpendicular to the bottom wall 11. An opening 15 is defined at one side of the rear wall 13.

The power supply chassis 30 includes a first sidewall 31, a second sidewall 33, and a top wall 35 connected to the first sidewall 31 and the second sidewall 33. The first sidewall 31, the second sidewall 33, and the top wall 35 cooperatively define an opening 37. In the power supply chassis 30 are two opposite supporting flanges 311, 331 respectively extending from the first sidewall 31 and the second sidewall 33. Two first securing slots 313 are defined in the first sidewall 31 adjacent a rear side of the power supply chassis 30. Two second securing slots 333 are defined in the second sidewall 31 adjacent a rear side of the power supply chassis 30.

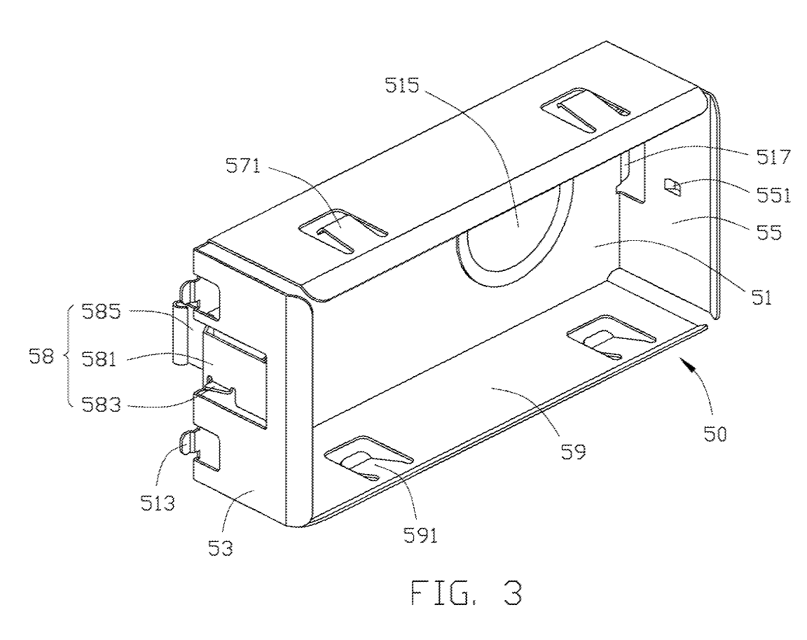

Referring to FIG. 3, the EMI shielding member 50 includes a rear wall 51. A first sidewall 53, a second sidewall 55, a top wall 57, and a bottom wall 59 perpendicularly extend from side edges of the rear wall 51. Two elastic clips 571 are formed on the top wall 57. The bottom wall 59 also forms an elastic clip 591. A slit 56 is defined between every adjacent two of the first sidewall 53, the second sidewall 55, the top wall 57 and the bottom wall 59.

The first sidewall 53 forms an elastic securing member 58. The elastic securing member 58 includes a main body 581, and a triangle-shape securing tab 583 configured to engage in the securing slot 313 of the power supply chassis 30. An operating handle 585 extends out from a free end of the elastic securing member 58.

A slot 511 is defined in the EMI shielding member rear wall 51 adjacent to the first sidewall 53. The slot 511 is configured to provide a space for the elastic securing member 58 moving therein to disengage from the securing slot 313 in the power supply chassis 30. Two first blocking tabs 513 extend from a side edge of the rear wall 51 adjacent to the first sidewall 53. The two first blocking tabs 513 are configured to abut a side edge of the power supply chassis sidewall 31. The rear wall 51 defines an operating hole 515 configured for a user's finger inserting therein to operate the elastic securing member 583. A second blocking tab 517 extends laterally from a side edge of the rear wall 51 adjacent to the second sidewall 55. The second blocking tab 517 is configured to abut against a side edge of the power supply chassis 33. A wedge shaped securing block 551, corresponding to the second securing slots 333 in the power supply chassis sidewall 35, protrudes from the EMI shielding member second sidewall 55.

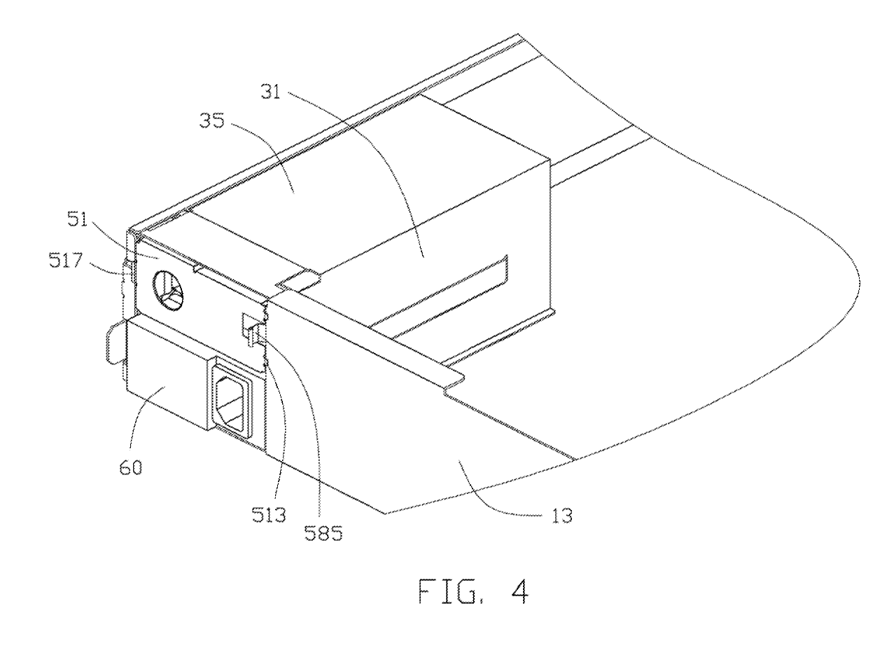

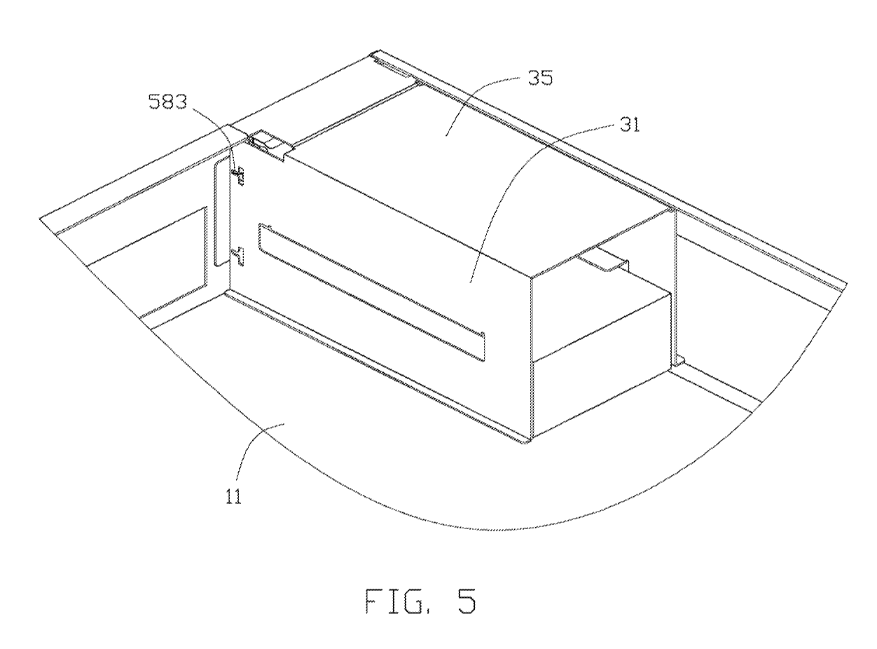

Referring to FIGS. 4 and 5, in assembly, the power supply 60 is mounted in the power supply chassis 30 through the opening 37. In the present embodiment, the power supply 60 is mounted in a lower portion of the receiving space of the power supply chassis 30. An upper portion of the receiving space is empty. The EMI shielding member 50 is disposed in the empty space between the power supply chassis top wall 35 and the power supply 60. The rear wall 51 of the EMI shielding member 50 and the power supply 60 cooperatively enclose the opening 37. The EMI shielding member top wall 57 abuts the power supply chassis top wall 35 with the elastic clip 571 being depressed. The EMI shielding member bottom wall 59 sits on the power supply 50. The elastic clip 591 on the bottom wall 59 is depressed by the power supply 60, and the elastic clips 61 on the power supply 60 is depressed by the EMI shielding member bottom wall 59. The securing tab 583 of the elastic securing member 58 engages in the first securing slot 313. The securing block 551 engages in the second securing slot 333. The first blocking tabs 513 and second blocking tab 517 respectively abut the side edges of the power supply chassis sidewalls 31 and 33, to prevent the EMI shielding member 50 from moving into the power supply chassis 30. Thus, the EMI shielding member 50 is secured to the power supply chassis 30 and blocks the opening 37. Then, the power supply chassis 30 is secured into the base 10 through the opening 15. The electronic device is thus assembled and provides good EMI shielding performance.

To disassemble, a user inserts a finger into the operating opening 515 in the EMI shielding member rear wall 51 and manipulates the operating handle 585 of the elastic member 58 with another finger. The elastic member 58 is deflected and moved in the slot 511. The securing tab 583 is disengaged from the first securing slot 313 of the power supply chassis sidewall 31. Thus, the EMI shielding member is removed from the power supply chassis 30. Another power supply can be mounted in the empty receiving space of the power supply chassis 30.

It is to be understood, however, that even though numerous characteristics and advantages of the embodiments have been set forth in the foregoing description, together with details of the structure and function of the present disclosure, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. An electronic device, comprising:
a base;
a power supply chassis mounted in the base and defining a receiving space, a power supply accommodated in the power supply chassis and occupying part of the receiving space, the power supply and the power supply chassis cooperatively defining an opening, a securing slot is defined by the power supply chassis; and
a shielding member blocking the opening, an elastic securing member located on the shielding member, the elastic securing member engaging with the securing slot.

2. The electronic device of claim 1, wherein the power supply chassis comprises two opposite sidewalls; the shielding member comprises a rear wall blocking the opening, a first sidewall and a second sidewall respectively abutting the two power supply sidewalls.

3. The electronic device of claim 1, wherein a securing tab protrudes from the elastic member, and is inserted in the securing slots.

4. The electronic device of claim 1, wherein an operating handle extends from the elastic securing member, the shielding member defines a slot configured for the operating handle moving therein.

5. The electronic device of claim 1, wherein the shielding member defines an operating hole configured for allowing a finger to be inserted therein.

6. The electronic device of claim 2, wherein the power supply chassis further comprises a top wall connected to the two sidewalls; the shielding member further comprises a top wall; the shielding member top wall abuts the power supply chassis top wall.

7. The electronic device of claim 1, wherein the shielding member further comprises at least one elastic clip, and the at least one elastic clip is depressed by the power supply.

8. The electronic device of claim 1, wherein the power supply further comprises at least one elastic clip, and the at least one elastic clip on the power supply is depressed by the shielding member.

9. The electronic device of claim 6, wherein a blocking tab extends laterally from the shielding member, the blocking tab abuts a side edge of the power supply chassis to prevent the shielding member from moving into the power supply chassis.

10. An electronic device, comprising:
a power supply chassis, the power supply chassis defines an opening;
a power supply accommodated in the power supply chassis through the opening; and
a shielding member accommodated in the power supply chassis, the shielding member abuts the power supply chassis, the power supply and the shielding member cooperatively fill the power supply chassis opening.

11. The electronic device of claim 10, wherein a securing slot is defined in one of the power supply chassis sidewalls; an elastic securing member is formed on the first sidewall of the shielding member; the elastic securing member engages in the securing slot.

12. The electronic device of claim 11, wherein a securing tab protrudes from the elastic securing member, and the securing tab engages the securing slots.

13. The electronic device of claim 10, wherein an operating handle extends from the elastic securing member, the shielding member defines a slot configured to provide a space for the operating handle moving therein.

14. The electronic device of claim 10, wherein the shielding member defines an operating hole configured to allow a finger to be inserted therein.

15. The electronic device of claim 10, wherein the shielding member comprises a top wall, the shielding member top wall abuts the power supply chassis.

16. The electronic device of claim 10, wherein the shielding member further comprises at least one elastic clip, and the at least one elastic clip is depressed by the power supply.

17. The electronic device of claim 10, wherein the power supply further comprises at least one elastic clip located on the power supply, and the at least one elastic clip on the power supply is depressed by the shielding member.
